(19) United States
(12) Patent Application Publication
(10) Pub. No.: US 2023/0420426 A1
(43) Pub. Date: Dec. 28, 2023

(54) COMPACT ARRAYS OF COLOR-TUNABLE PIXELS

(71) Applicant: Lumileds LLC, San Jose, CA (US)

(72) Inventor: Robert Armitage, Cupertino, CA (US)

(73) Assignee: Lumileds LLC, San Jose, CA (US)

(21) Appl. No.: 18/211,900

(22) Filed: Jun. 20, 2023

Related U.S. Application Data
(60) Provisional application No. 63/355,226, filed on Jun. 24, 2022.

(51) Int. Cl. H01L 25/075; H01L 33/62; H01L 33/06; H01L 33/46; H01L 33/32; H01L 33/38; H01L 33/40; H01L 33/00

(52) U.S. Cl. CPC H01L 25/0756; H01L 33/62; H01L 33/06; H01L 33/46; H01L 33/32; H01L 33/38; H01L 33/405; H01L 33/0075; H01L 2933/0066; H01L 2933/0016

(57) ABSTRACT

Provided is a monolithically integrated red green blue (RGB) light emitting diode (LED) array manufactured with a reduced number of mesa etching steps and contact terminals. The LED array may have two or three p-n-junctions grown sequentially on a wafer. One of the p-n junctions has the opposite order of deposition of the n- and p-layers. A light-emitting active region is embedded between the n- and p-layers of each of the p-n junctions. Each active region emits light of different wavelength. The wafer is etched into multi-level mesas, creating two separate voltage terminals and a ground contact to control the bias between particular semiconductor layers. All of the p-n junctions share a common ground contact.

### CROSS-REFERENCE TO RELATED APPLICATIONS

This application claims priority to U.S. Provisional Application No. 63/355,226, filed Jun. 24, 2022, the entire disclosure of which is hereby incorporated by reference herein.

### TECHNICAL FIELD

Embodiments of the disclosure generally relate to arrays of light emitting diode (LED) devices and methods of manufacturing the same. More particularly, embodiments are directed to monolithically integrated red, green, blue (RGB) emitter arrays having a reduced number of mesa etching steps and contact terminals.

### BACKGROUND

Visualization systems, such as virtual reality systems and augmented reality systems, are becoming increasingly more common in the fields such as entertainment, education, medicine, and business. There is ongoing effort to improve visualization systems, such as virtual reality systems and augmented reality systems.

Micro-LEDs (μLEDs) may be small size LEDs (typically ˜50 μm in diameter or smaller) that can be used to produce very high-resolution color displays when μLEDs of red, green, and blue wavelengths may be aligned in close proximity. Manufacture of an μLED display typically involves picking singulated μLEDs from separate blue, green and red WL wafers and aligning them in alternating close proximity on the display.

There is interest in high-resolution color LED displays requiring microscopic pixel pitches. Assembling red, green, and blue LEDs grown on separate wafers becomes difficult when the sizes of the LEDs are in the range of tens of microns or smaller. Monolithic RGB integration is an approach that avoids the problem of manipulating microscopic LEDs into the right positions on the display but comes with its own set of challenges. Current monolithic RGB arrays requires at least three biased terminals plus a ground connection. In a high-resolution display, there is limited space available for making all of these mesa etches and terminals, making it difficult to practically implement designs.

Other approaches to monolithic RGB use one p-n junction that contains quantum wells of three colors. Depending on the applied bias, relatively more or less light is generated in particular wells allowing for some control over the color point. Such approaches are appealing insofar as they work with only two terminals per pixel, but an excess voltage across the active region is inevitable, and filters are required to obtain color characteristics acceptable for displays. Thus, this approach simplifies die fabrication but is not well suited to making efficient displays with low power consumption.

Accordingly, there is a need for improved μLED devices and for improved methods of manufacture.

### SUMMARY

Embodiments of the disclosure are directed to light emitting diode (LED) arrays and methods for manufacturing LED arrays. In one or more embodiments, a light emitting diode (LED) array comprises: a first light emitting stack on a second light emitting stack, the second light emitting stack on a third light emitting stack, the third light emitting stack on a reflective p-contact electrode bonded to a backplane, wherein the first light emitting stack comprises a first electrical contact on a first n-type layer on a first color active region, the first color active region on a first p-type layer, and the first p-type layer on a first tunnel junction, the second light emitting stack comprises a second electrical contact on a second n-type layer in contact with the first tunnel junction and on a second tunnel junction, the second tunnel junction on a second p-type layer, and the second p-type layer on a second color active region, and the third light emitting stack comprises a third electrical contact on a third n-type layer in contact with the second color active region and on a third p-type layer.

Further embodiments of the disclosure are directed to methods of manufacturing an LED array. In one or more embodiments, the method comprises: sequentially forming at least three p-n junctions on an epitaxial wafer to form an epitaxial stack, the epitaxial stack comprising at least one n-type layer and at least one p-type layer and having a color active region embedded between the at least one n-type layer and at least one p-type layer; depositing a reflective p-contact electrode on the epitaxial stack; bonding the reflective p-contact electrode to a backplane wafer; dry etching the epitaxial stack to access the at least one n-type layer to form electrical contacts and a mesa; conformally depositing a dielectric layer over the mesa; removing a portion of the dielectric layer to form a dielectric opening on a top surface of the mesa, the dielectric opening exposing the at least one n-type layer; depositing Ohmic contacts in the dielectric opening to form an electrical contact; depositing a conformal metal layer over a portion of the mesa and forming a gap across a center of the mesa to allow light out; and depositing an electrode grid over a top of the LED array.

Additional embodiments of the disclosure are directed to visualization or display systems. In one or more embodiments, a visualization system comprises: a battery; a radio; a sensor; a video generation process; a light source comprising the LED array of one or more embodiments described herein; a modulator; a modulation processor; a beam combiner; a projection optic; a screen; and a lens.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method of manufacturing an LED array according to one or more embodiments;

FIGS. 2A and 2B are schematics illustrating how the reversed order of p- and n-layers facilitates control of the emission wavelength with applied voltage;

FIG. 3 is a graph illustrating the measured data for LEDs of opposite polarizations and the same quantum well design according to one or more embodiments;

FIG. 4 is a graph illustrating the measured spectra for a red-green switchable color LED with p-GaN grown before the quantum wells according to one or more embodiments;

FIG. 5 is a cross-sectional view of epitaxy to be used in an LED variation before processing according to one or more embodiments;

FIG. 6 is a cross-sectional view of a μLED array after processing the LED variation illustrated in FIG. 5 according to one or more embodiments;

FIG. 7 is a top-down schematic of the μLED array illustrated in FIG. 6;

FIG. 8 is a top view arrangement of conformal dielectric layers, which are under the metal lines illustrated in the μLED array illustrated in FIG. 7;

FIG. 9 is a cross-sectional view of epitaxy to be used in an alternative LED variation before processing according to one or more embodiments;

FIG. 10 is a cross-sectional view of a μLED array after processing the alternative LED variation illustrated in FIG. 9 according to one or more embodiments; and

FIG. 11 illustrates a block diagram of an example of a visualization system using the μLED array of one or more embodiments.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features, or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Examples of different light illumination systems and/or light emitting diode (LED) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flashlights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro-LED arrays, etc.) may be used for applications where more brightness is desired or required.

The present disclosure generally relates to the manufacture of micro light emitting diode (μLED) displays and of multi-wavelength light emitters with large bandwidth for free-space visible light communications. Epitaxial tunnel junctions may be used to combine multiple emission wavelengths within a single LED device.

Manufacturing μLEDs could be simplified if two or more active regions emitting different wavelengths may be integrated within a single wafer. Such an approach may be possible within the AlInGaN materials system since it has been demonstrated that blue, green, and red LEDs can all be made in this system. However, use of a multi-color chip in a μLED display requires not only stacking multiple layers able to emit at different wavelengths within a single epitaxial growth run, but also requires an ability to change respective emission intensity ratios between the emitters of different wavelengths.

In one or more embodiments, bias-based control of the LED color is used to reduce the number of terminals down to a more manageable number than in current technology. Some independent control of separate junctions, however, is used to avoid the problems of poor color purity and high voltage inherent in other approaches. Additionally, one or more embodiments provides an improved way of controlling the LED wavelength through voltage.

In one or more embodiments, “reverse polarity” LEDs are advantageously used for display applications. As used herein, the term “reverse polarity” refers to growing the p-GaN layer of the LED before the quantum wells, instead of after the quantum wells. There has been a widely held perception that high-efficiency p-side down LEDs are infeasible due to unintentional acceptor dopant incorporation in the quantum wells. In one or more embodiments, however, it has been advantageously found that the above problem can be mitigated using special growth conditions. The reverse polarity LED is so-named because the directions of the p-n junction and InGaN polarization fields are reversed from traditional means.

As used herein, the term “p-n junction” refers to a boundary between two semiconductor layers of opposite conductivity types p-type and n-type. The “p” side contains an excess of holes, while the “n” side contains an excess of electrons. The excesses of holes and electrons may be obtained by intentional doping with acceptor or donor impurities, respectively, and/or may result from the presence of native crystal defects. Said boundary is not necessarily abrupt, planar, or smooth. Said boundary may include of gradients in impurity concentration and/or layers of intrinsic (neutral) conductivity type between the p-type and n-type layers. Said boundary may feature protrusions of p-type semiconductor into the n-type semiconductor, or vice-versa.

The embodiments of the disclosure are described by way of the Figures, which illustrate devices and processes for forming devices in accordance with one or more embodiments of the disclosure. The processes shown are merely illustrative possible uses for the disclosed processes, and the skilled artisan will recognize that the disclosed processes are not limited to the illustrated applications.

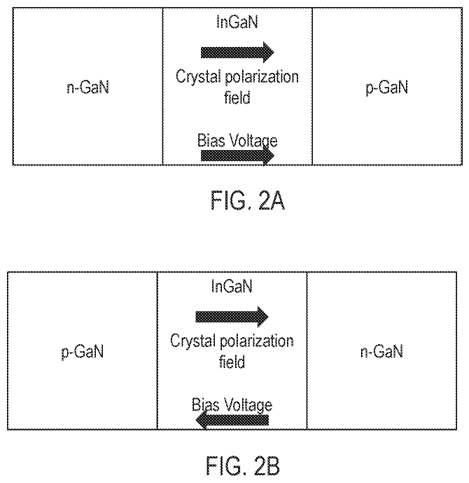

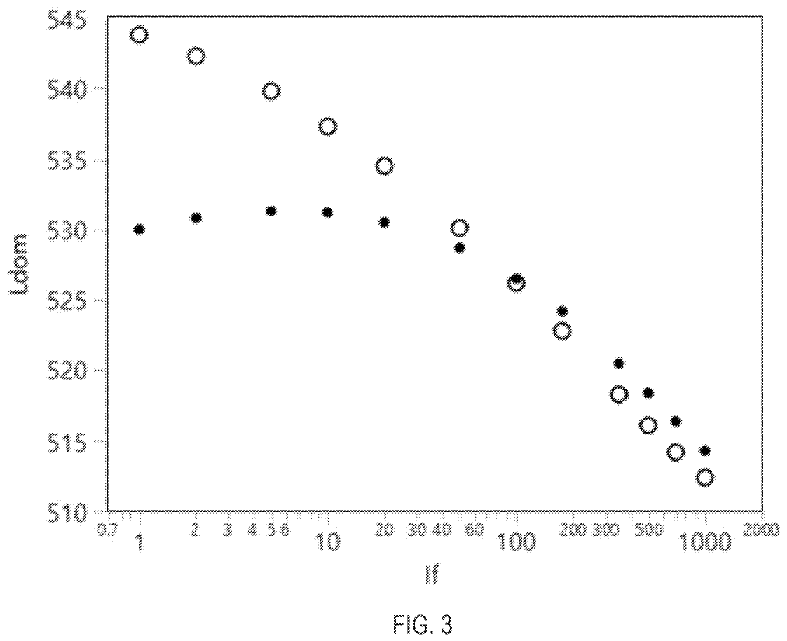

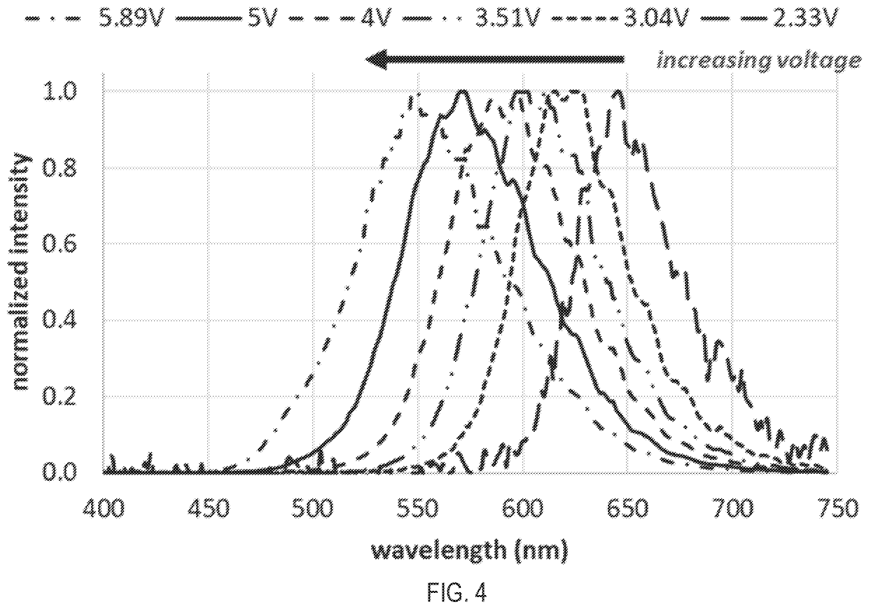

In one or more embodiments, the reversed orientation of the polarity facilitates control of the net electric field across the quantum well(s) in a way that is favorable for controlling the wavelength. The advantage of the concept is conceptually illustrated in FIGS. 2A, 2B, 3, and the measured spectra of a color-shifting LED are shown in FIG. 4.

FIGS. 2A and 2B illustrate schematics of how the reversed order of p- and n-layers facilitate control of the emission wavelength with applied voltage. A larger magnitude of the electric field across the indium gallium nitride (InGaN) quantum well increases the wavelength due to the quantum-confine Stark effect. The graph illustrated in FIG. 3 shows measured data for LEDs of opposite polarization and the same quantum well design.

FIG. 4 is a graph illustrating the measured spectra for a red-green switchable color LED with p-GaN grown before the quantum wells. The spectrum is characterized by a distinct peak that changes with voltage, not multiple peaks with voltage-dependent heights as in existing LEDs using multiple quantum wells of different colors in the same active region. The quantum well in FIG. 4 is wider than the quantum well illustrated in FIGS. 2A and 2B allowing for a larger wavelength shift with voltage.

The μLED array of one or more embodiments advantageously requires fewer contact terminals and mesa etches when compared to known μLED arrays. The μLED array of one or more embodiments requires only two independently biased terminals and a common ground electrode. Additionally, the μLED array of one or more embodiments allows for better control of emission color than in known single junction RGB technologies. Without intending to be bound by theory, it is thought that the μLED arrays of one or more embodiments are capable of lower display power consumption than published single junction RGB technologies.

In one or more embodiments, two or three light emitting stacks are grown sequentially on the same epitaxial wafer. One of these junctions has the opposite order of deposition of the n- and p-layers as compared to the other(s). In one or more embodiments, a light-emitting active region is embedded between the n- and p-layers of each of the junctions. Each active region emits light of different wavelength than the other active region(s). At least one junction has the property that its emission shifts from one of the primary colors to a different (shorter) primary color as the bias across the junction increases. For example, the emission may shift from red to green, or from green to blue.

In one or more embodiments, the epitaxy includes at least one tunnel junction to avoid the need for contacts to etched p-GaN layers. The wafer is etched into multi-level mesas creating two separate voltage terminals and a ground contact to control the bias between particular semiconductor layers. All of the junctions share a common ground contact.

One or more alternative embodiments provides a two-junction device which controls the color emitted by one of the junctions by varying the voltage on one terminal. For example, the color may be changed from red to green by increasing the voltage. Radiance can be matched for red and green by decreasing the pulse-width modulation cycle when the bias voltage is increased. Blue emission is controlled with an independent contact terminal to the third (blue) active region. The color-changing functionality with voltage is facilitated by the reversed-from-usual orientation of the p-n junction field relative to InGaN quantum well polarization fields.

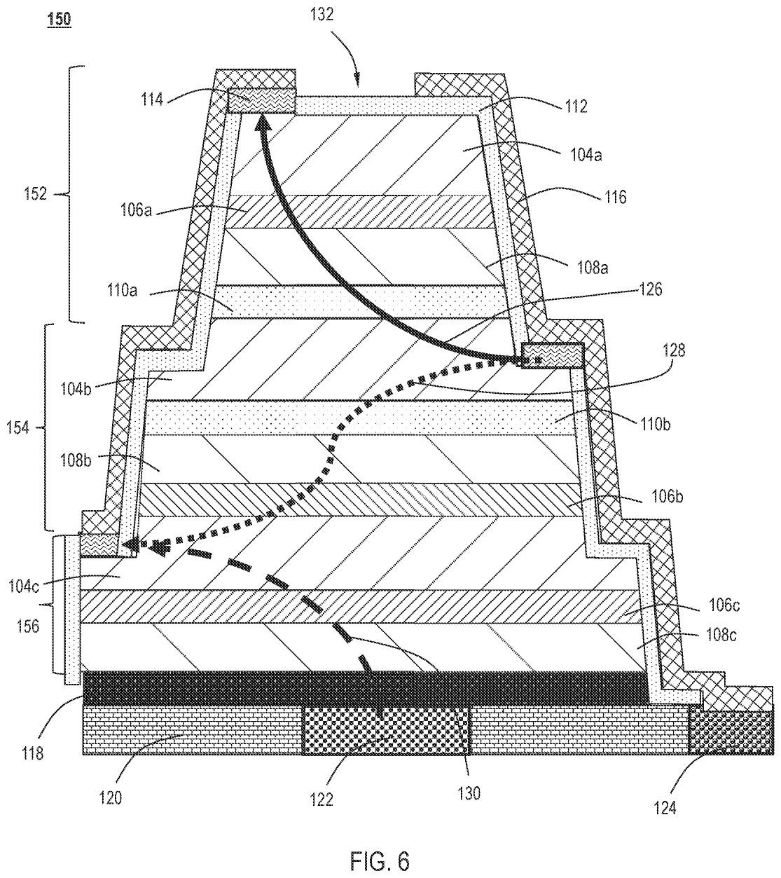

In the detailed examples illustrated in the Figures and described below, blue light is produced with an independent driving voltage (applied to Terminal A in FIGS. 6 and 10). Alternative implementations, however, in which the red active region is interchanged with the blue active region are also possible. In those implementations red light is emitted with a bias to Terminal A, and the magnitude of the bias to Terminal B can be used to adjust the emission of the other color from green to blue.

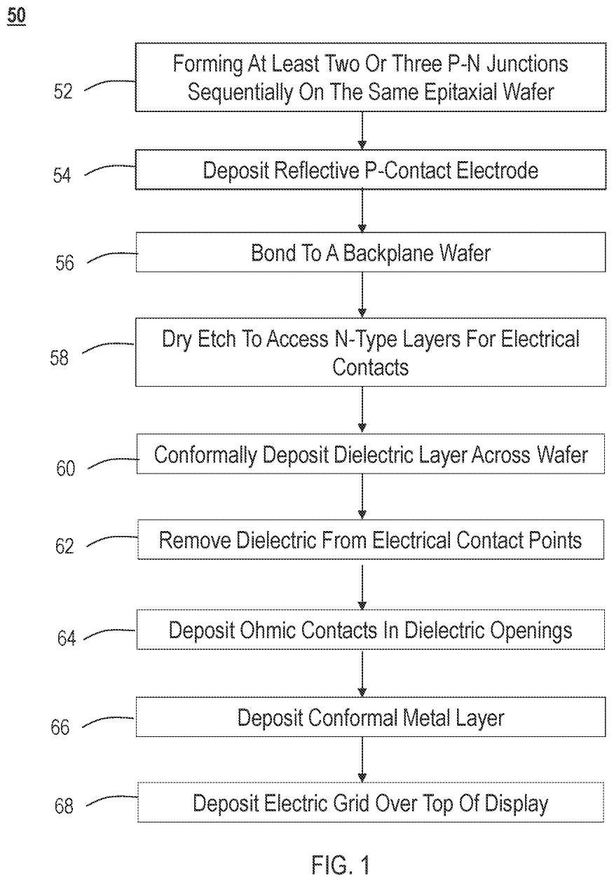

FIG. 1 illustrates a process flow diagram of a method 50 of manufacturing a micro light emitting diode (μLED) array according to one or more embodiments of the present disclosure. With reference to FIG. 1, in one or more embodiments, the method begins at operation 52 by forming two or three p-n junctions sequentially on the same epitaxial wafer to form an epitaxial stack, the epitaxial stack including at least one n-type layer and at least one p-type layer and having a color active region embedded between the at least one n-type layer and at least one p-type layer. At operation 54 a reflective p-contact electrode is deposited on the epitaxial stack. At operation 56, the epitaxial stack with the reflective p-contact is bonded to a backplane wafer. At operation 58, the epitaxial stack is dry etched to access the n-type layers for formation of electrical contacts and a mesa. At operation 60, a dielectric layer is conformally deposited across the epitaxial wafer over the mesa. At operation 62, a portion of the dielectric layer is removed to form a dielectric opening on a top surface of the mesa, the dielectric opening exposing the at least one n-type layer. At operation 64, Ohmic contacts are deposited in the dielectric openings to form electrical contacts. At operation 66, a conformal reflective metal layer is deposited over a portion of the mesa and forming a gap across a center of the mesa to allow light out. At operation 68, an electrode grid is deposited over the top of the LED array.

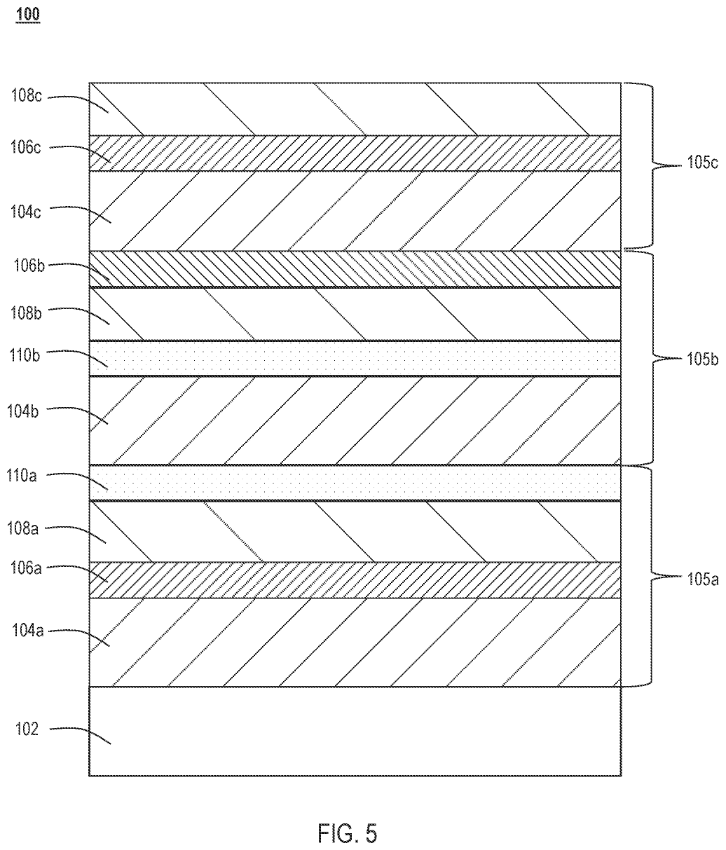

Referring to FIG. 5, the epitaxial growth steps for the first variation 100, variant A, are described. FIG. 5 illustrates a cross-sectional view of a μLED array 100 according to one or more embodiments. An aspect of the disclosure pertains to a method of manufacturing a μLED array. Referring to FIG. 5, a first variation 100, variation “A”, is a three-junction device with the first and second p-n junctions (of opposite p-n deposition orders) sharing a common n-type layer connected to one of the electrical terminals. While those two junctions are driven in parallel (not independently) the aggregate color of their emission can be controlled by voltage. For example, when a red and green active region are connected in parallel, current only flows through the red region at low voltage. The red active region can be designed such that its emission shifts to green at high voltage and is additive with light emitted by the green active region. Blue emission is controlled with an independent contact terminal to the third (blue) active region.

Referring to FIG. 5, a μLED array 100 is manufactured by forming a plurality of III-nitride layers on a substrate 102 to form three-junction LED on the substrate including color-active regions. The color active regions include a first color active region 106a, a second color active region 106b, and a third color active region 106c. Any order of stacking the different color active regions is within the scope of the disclosure.

According to certain specific embodiments, the LED array 100 comprises three or more p-n junctions. In one or more embodiments, a first light emitting stack 105a has a first n-type layer 104a formed on the substrate 102, a first color active region 106a formed on the first n-type layer 104a, a first p-type layer 108a formed on the first color active region 106a, and a first tunnel junction 110a formed on the first p-type layer 108a. The first p-n junction includes the first n-type layer 104a and the first p-type layer 108a separated by the first color active region 106a.

In one or more embodiments, the first color active region 106a is a blue color active region. In the embodiment shown, there is a first tunnel junction 110a on the first light emitting stack, in particular on the first p-type layer 108a. A tunnel junction is a structure that allows electrons to tunnel from the valence band of a p-type layer to the conduction band of an n-type layer in reverse bias. When an electron tunnels, a hole is left behind in the p-type layer, such that carriers are generated in both regions. Accordingly, in an electronic device like a diode, where only a small leakage current flows in reverse bias, a large current can be carried in reverse bias across a tunnel junction. A tunnel junction comprises a particular alignment of the conduction and valence bands at the p-n tunnel junction. This can be achieved by using very high doping (e.g., in the p++/n++ junction). In addition, III-nitride materials have an inherent polarization that creates an electric field at heterointerfaces between different alloy compositions. In some circumstances, this polarization field can also be utilized to achieve band alignment for tunneling.

Still referring to FIG. 5, the μLED array 100 further comprises a second light emitting stack 105b on the first light emitting stack 105a. As recognized by one of skill in the art, the second light emitting stack 105b may not be a self-contained light emitting stack. In one or more embodiments, electrons need to be injected from layer 104c (which is part of the third group 105c) to emit light from second active region 106b. The second light emitting stack 105b includes a second n-type layer 104b on the first tunnel junction 110a, a second tunnel junction 110b on the second n-type layer 104b, a second p-type layer 108b on the second tunnel junction 110b, and a second color active region 106b on the second p-type layer 108b. In one or more embodiments, the second color active region 106b is a red color active region. In the embodiment shown, there is a second tunnel junction 110b on the second junction 105a, in particular on the second n-type layer 104b. When the second n-type layer 104b is biased positively relative to second p-type layer 108b, a hole current flows in the second p-type layer 108b through the second tunnel junction 110b. The second tunnel junction 110b is itself a (second) p-n junction, comprised of n- and p-type layers which are not shown separately in the figure. The second p-type layer 108b serves to inject holes required to excite luminescence from the second color active region 106b.

The third light emitting stack 105c is formed on the second light emitting stack 105b and has a third n-type layer 104c on the second color active region 106b, a third color active region 106c on the third n-type layer 104c, and a third p-type layer 108c on the third color active region 106c. The third n-type layer 104c serves to inject electrons into both the second color active region 106b of the second light emitting stack and the third color active region 106c of the third light-emitting stack. The third p-n junction includes the third n-type layer 104c and the third p-type layer 108c separated by the third color active region 106c.

In one or more embodiments, a first n-type layer 104a is formed on the substrate 102. The substrate 102 may be any substrate known to one of skill in the art which is configured for use in the formation of LED devices. In one or more embodiments, the substrate 102 comprises one or more of sapphire, silicon carbide, silicon (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate is 102 not patterned and can be considered to be flat or substantially flat. In other embodiments, the substrate 102 is a patterned substrate.

In one or more embodiments, the first n-type layer 104a, the second n-type layer 104b, and the third n-type layer 104c may comprise any Group III-V semiconductors, including binary, ternary, and quaternary alloys of gallium (Ga), aluminum (Al), indium (In), and nitrogen (N), also referred to as III-nitride materials. Thus, in some embodiments, the first n-type layer 104a, the second n-type layer 104b, and the third n-type layer 104c independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the first n-type layer 104a, the second n-type layer 104b, and the third n-type layer 104c comprise gallium nitride (GaN). In one or more embodiments, the first n-type layer 104a, the second n-type layer 104b, and the third n-type layer 104c are independently doped with n-type dopants, such as silicon (Si) or germanium (Ge). In one or more embodiments, the dopant concentration is in a range of from 1 e17 to 2e19 cm³.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneous or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step may be conducted between the deliveries of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, μLED array 100 is manufactured by placing the substrate 102 in a metalorganic vapor-phase epitaxy (MOVPE) reactor so that the μLED array layers are grown epitaxially.

In one or more embodiments, the first p-type layer 108a, the second p-type layer 108b, and the third p-type layer 108c may independently comprise any Group III-V semiconductors, including binary, ternary, and quaternary alloys of gallium (Ga), aluminum (Al), indium (In), and nitrogen (N), also referred to as III-nitride materials. Thus, in some embodiments, the first p-type layer 108a, the second p-type layer 108b, and the third p-type layer 108c independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

In some embodiments, the first p-type layer 108a, the second p-type layer 108b, and the third p-type layer 108c independently comprise a sequence of doped p-type layers. In one or more embodiments, the first p-type layer 108a, the second p-type layer 108b, and the third p-type layer 108c independently comprise a gallium nitride (GaN) layer. The first p-type layer 108a, the second p-type layer 108b, and the third p-type layer 108c may be independently doped with any suitable p-type dopant known to the skilled artisan. In one or more embodiments, the first p-type layer 108a, the second p-type layer 108b, and the third p-type layer 108c may independently be doped with magnesium (Mg). In one or more embodiments, the first p-type layer 108a, the second p-type layer 108b, and the third p-type layer 108c independently comprise a first magnesium doped p-type aluminum gallium nitride layer, a magnesium doped p-type gallium nitride layer, and a second magnesium doped p-type aluminum gallium nitride layer.

In one or more embodiments, the key differentiators for the epitaxy used in this μLED array versus known μLED arrays are the reverse polarization orientation discussed above and the use of wider than typical quantum wells in an application where a large color shift is intentionally wanted. For example, the well width that optimizes internal quantum efficiency (IQE) might be 3 nm, whereas it might be preferable to increase the width to 5 nm in one or more embodiments. In one or more embodiments, the well width may be in a range of from 2 nm to 8 nm.

FIG. 6 illustrates a cross-section schematic after processing the first variation 100 into a microLED array. The arrows 126, 128, 130, having different dash patterns, indicate the recombination paths resulting in red, green, and blue emission. In one or more embodiments, when terminal A 122 has a voltage of about 3 volts and terminal B 124 has a voltage of about 0 volts, blue light 130 results. In one or more embodiments, when terminal A 122 has a voltage of about 0 volts and terminal B 124 has a voltage of above 3 volts or greater, a red light 128 results. In one or more embodiments, when terminal A 122 has a voltage of about 0 volts and terminal B has a voltage of about 5 volts or greater, a green light 126 (or a reddish-green light) results. A color-shifting red active region similar to the one illustrated in FIG. 4 may be used that produces red emission with small bias on terminal B 124 and extra green emission with large bias on terminal B 124. As recognized by one of skill in the art, the first variation 100 as presented in FIG. 6 has been rotated 180 degrees relative to its depiction in FIG. 5.

Referring to FIG. 6, a microLED wafer 150 is fabricated with a first step of acceptor activation anneal. A reflective p-contact electrode (p-mirror) 118 is deposited. The reflective p-contact electrode (p-mirror) 118 may comprise any suitable material known to the skilled artisan. In one or more embodiments, the reflective p-contact electrode (p-mirror) 118 comprises one or more of aluminum (Al), platinum (Pt), silver (Ag), and the like. In other embodiments, the reflective p-contact electrode (p-mirror) 118 may comprise a bilayer of a reflective material (i.e., one or more of aluminum (Al), platinum (Pt), silver (Ag), and the like) and indium tin oxide (ITO), with the ITO being the part of the bilayer in direct contact with the third p-type layer 108c.

In one or more embodiments, the reflective p-contact electrode (p-mirror) 118 is then bonded to a backplane wafer 120, which might be pre-coated with similar metals to facilitate wafer bonding. In one or more embodiments, the backplane wafer 120 contains vias 122 and 124 between the bonding surface and circuitry within or on the opposite face of the backplane wafer 120.

Still referring to FIG. 6, in one or more embodiments, the first n-type layer 104a, the second n-type layer 104b, and the third n-type layer 104c are etched, e.g., by dry etching, to form openings for electrical contacts 114, to isolate pixels, and to access the via 124 to backplane terminal B. In one or more embodiments, there are a total of three etch levels 152, 154, and 156, which is a more manageable number than in known μLED arrays.

In one or more embodiments, a dielectric layer 112 is conformally deposited on the entire wafer 150. As used herein, the term “dielectric” refers to an electrical insulator material that can be polarized by an applied electric field. In one or more embodiments, the dielectric layer includes, but is not limited to, oxides, e.g., silicon oxide (SiO₂), aluminum oxide (Al₂O₃), nitrides, e.g., silicon nitride (Si₃N₄). In one or more embodiments, the dielectric layer comprises silicon nitride (Si₃N₄), silicon oxide (SiO₂), or a multi-layer of silicon dioxide (SiO₂) and silicon nitride (Si₃N₄). In some embodiments, the dielectric layer composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 112 is removed from electrical contact points using dry etching. Ohmic contact metal layers 114 are deposited and formed in the dielectric openings. Each of the ohmic contact metal layers 114 are to the n-type layer 104a, 104b, and 104c, and may be the same metal. The ohmic contact metal layers 114 may comprises any suitable metal known to the skilled artisan. In one or more embodiments, the Ohmic contact metal layers 114 comprise aluminum (Al).

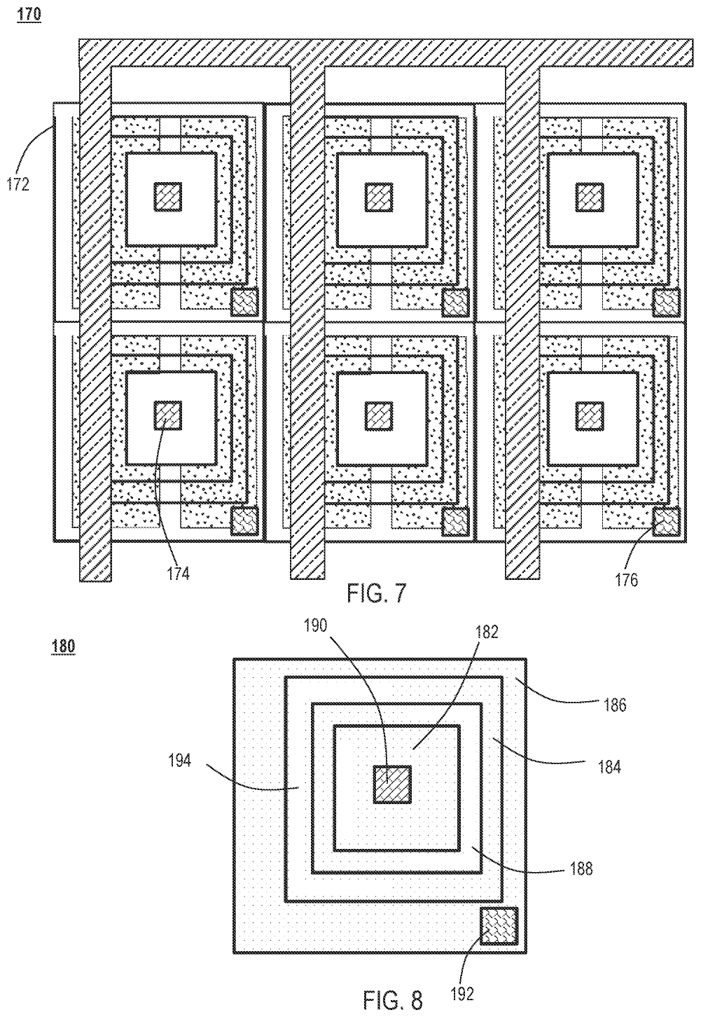

Still referring to FIG. 6, a thick, partly conformal metal layer 116 is deposited over most of the mesa area. A gap 132 is left across the center of the mesa to allow light out and to electrically isolate 124 Terminal B from ground, as illustrated in FIGS. 6 and 7. The partly conformal metal layer 116 may comprise any suitable material known to the skilled artisan. In one or more embodiments, the partly conformal metal layer 116 has high reflectivity and stability. In one or more embodiments, the partly conformal metal layer 116 comprises aluminum (Al) or platinum (Pt). The layer 116 may be comprised of a stack of multiple different metal thin films, for example a first metal such as Al or silver (Ag) with the property of high reflectivity and second metal with better chemical stability such as titanium (Ti), chromium (Cr), tungsten (W), gold (Au) or Pt. The partly conformal metal layer 116 connects the second n-type layer 104b with the via 124 to backplane Terminal B.

FIG. 7 illustrates a top-down schematic of the array 150 that is illustrated in cross-section in FIG. 6. The section illustrated in FIG. 7 corresponds to the northwest corner of a much larger display. In one or more embodiments, an electrode grid 172 of ground lines is deposited over the reflective partly conformal metal layer 116 on one side of each pixel, as illustrated in FIG. 7. The electrode grid 172 connects to a ground line at the perimeter of the display 150. In one or more embodiments, the electrode grid 172 connects the ground terminal (left side of FIG. 6) to a ground electrode at the perimeter of the display.

Referring to FIGS. 6 and 7, in one or more embodiments, blue light 130 is emitted when Terminal A 174 is biased above ground potential (i.e., +3 V) and Terminal B 176 is at ground (i.e., 0 V). In one or more embodiments, when Terminal A 174 at ground (i.e., 0 V), either red light 128 or green light 126 can be generated with bias to Terminal B 176, depending upon the magnitude of the bias. For example, if the bias to Terminal B is in a range of from about 3 V to less than 5 V, red light 128 can be generated, and if the bias to Terminal B 176 is greater than 5 V, green light 126 can be generated. Although the first color active region 106a and the second color active region 106b are connected in parallel, they can be designed such that current only flows through the second color (red) active region 106b for a small bias. Thus, only red light 128 is generated. For a larger bias on terminal B 176, current flows through both the red and green active regions, however the generated color can be predominantly green due to higher IQE of the green active region relative to the red, and the natural tendency for the red emission to shift shorter in wavelength at higher current density. The green color purity may be further enhanced using a “red” active region such as the one in FIG. 4, which itself emits green (not red) light at high current density. The pulse width modulation duty cycle can be reduced for the green operating mode to make the radiance similar to the red mode with a higher duty cycle.

FIG. 8 illustrates a top view arrangement of conformal dielectric layers 182, 184, 186 that are deposited over the entire surface following the last mesa etching step. In one or more embodiments, the conformal dielectric layers 182, 184, 186 are under the electrode grid 172 illustrated in FIG. 7. Referring to FIGS. 6 to 8, areas 188, 194 indicate where dielectric layers 182, 184, 186 are removed by subsequent etching to access the Ohmic contact metal layers 114 on the pixel. The conformal dielectric layers 182, 184, 186 are also used to access the via 192 which connects to the Terminal B in the backplane and to access the via 190 which connects to Terminal A.

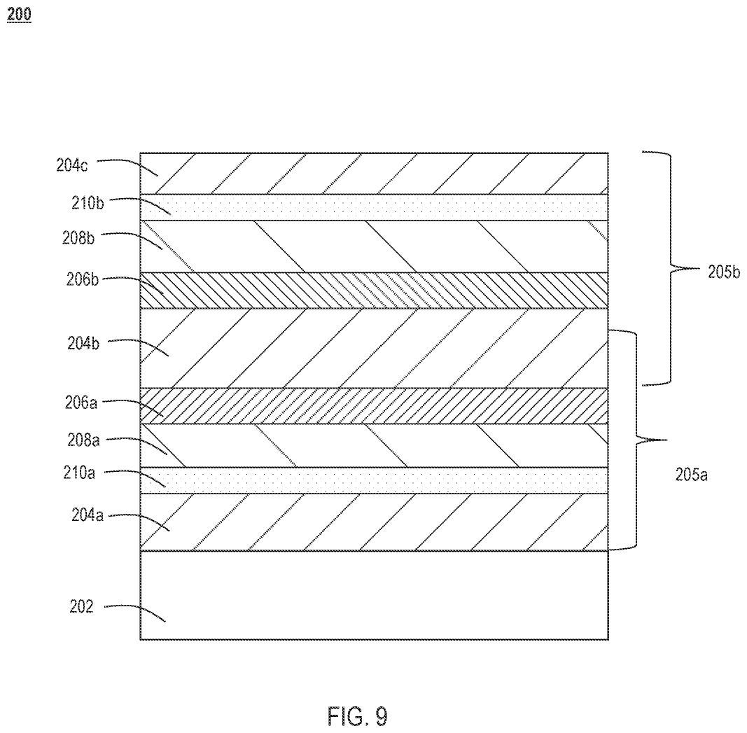

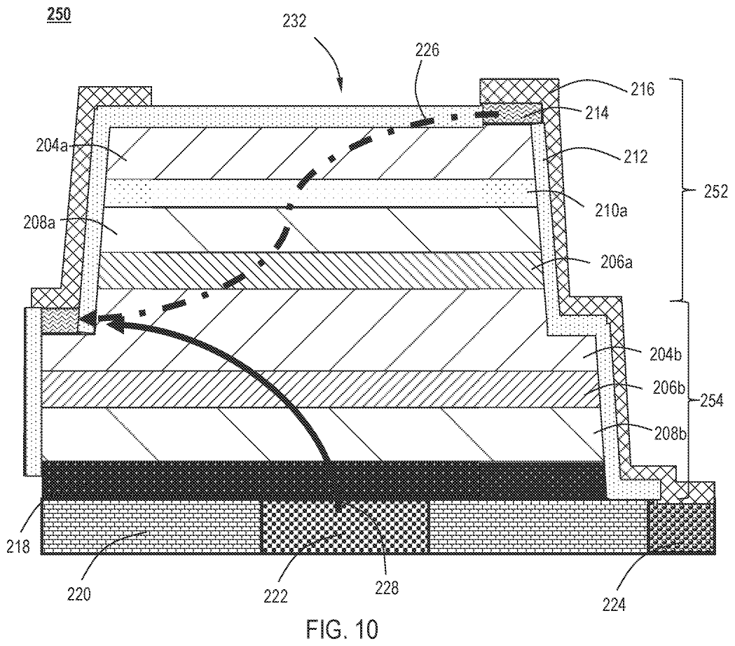

Referring to FIG. 9, the epitaxial growth steps for the second variation 200, variant B, are described. FIG. 9 illustrates a cross-sectional view of a μLED array 200 according to one or more embodiments. An aspect of the disclosure pertains to a method of manufacturing a μLED array. Referring to FIG. 9, a second variation 200, variation “b”, is a two-junction device with the first and second junctions (of opposite p-n deposition orders) sharing a common n-type layer connected to one of the electrical terminals. In one or more embodiments, Variation B 200 has a simpler epitaxial structure and a simpler mesa surface topography than Variation A 100. The microLED fabrication is realized with one fewer mesa etching level in Variation B 200. In Variation B 200, the first active region by itself supplies both the red and green light depending on bias to Terminal B, according to the mechanism demonstrated in FIG. 4.

Referring to FIG. 9, a μLED array 200 is manufactured by forming a plurality of III-nitride layers on a substrate 202 to form two-junction LED on the substrate including color-active regions. The color active regions include a first color active region 206a and a second color active region 206b. Any order of stacking the different color active regions is within the scope of the disclosure.

According to certain specific embodiments, the LED array 200 comprises a first light emitting stack 205a having a first n-type layer 204a formed on the substrate 202, a first tunnel junction 210a formed on the first n-type layer 204a, a first p-type layer 208a formed on the first tunnel junction 210a, a first color active region 206a formed on the first p-type layer 208a, and a second n-type layer 204b on the first color active region 206a.

In one or more embodiments, the first color active region 206a is a red/green color active region. In the embodiment shown, there is a tunnel junction 210a between the first n-type layer 204a and the first p-type layer 208a. This arrangement makes possible hole injection to first color active region 206a without needing to directly contact the surface of p-type layer 208a with a metal. Electrons are injected to the first color active region 206a from the second n-type layer 204b.

Still referring to FIG. 9, the μLED array 200 further comprises a second light emitting stack 205b on the first light emitting stack 205a. The second light emitting stack 205b includes the second n-type layer 204b, a second color active region 206b on the second n-type layer 204b, a second p-type layer 208b on the second color active region 206b. It should be noted that the second n-type layer 204b is “shared” between both the first and second light emitting stacks 205a and 205b. In other words, the second n-type layer 204b can be used to inject electrons to both the first active region 206a and the second active region 206b. The second n-type layer 204b may be comprised of a plurality of layers with different n-type doping concentrations. In one or more embodiments, the second color active region 206b is a blue color active region. Optionally, a second tunnel junction 210b and a third n-type layer 204c may be formed on the second p-type layer 208b. These optional layers can allow the wafer to be subjected to high-temperature processing (for example, high-temperature annealing to activate buried p-type layers) without damaging the p-type layer 208b.

In one or more embodiments, a first n-type layer 204a is formed on the substrate 202. The substrate 202 may be any substrate known to one of skill in the art which is configured for use in the formation of LED devices. In one or more embodiments, the substrate 202 comprises one or more of sapphire, silicon carbide, silica (Si), quartz, magnesium oxide (MgO), zinc oxide (ZnO), spinel, and the like. In one or more embodiments, the substrate 202 is a transparent substrate. In specific embodiments, the substrate 202 comprises sapphire. In one or more embodiments, the substrate 202 is not patterned prior to formation of the LEDs. Thus, in some embodiments, the substrate is 202 not patterned and can be considered to be flat or substantially flat. In other embodiments, the substrate 202 is a patterned substrate.

In one or more embodiments, the first n-type layer 204a, the second n-type layer 204b, and the optional third n-type layer 204c may comprise any Group III-V semiconductors, including binary, ternary, and quaternary alloys of gallium (Ga), aluminum (Al), indium (In), and nitrogen (N), also referred to as III-nitride materials. Thus, in some embodiments, the first n-type layer 204a, the second n-type layer 204b, and the third n-type layer 204c independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the first n-type layer 204a, the second n-type layer 204b, and the third n-type layer 204c comprise gallium nitride (GaN). In one or more embodiments, the first n-type layer 204a, the second n-type layer 204b, and the third n-type layer 204c are independently doped with n-type dopants, such as silicon (Si) or germanium (Ge).

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD), as discussed above.

In one or more embodiments, μLED array 200 is manufactured by placing the substrate 202 in a metalorganic vapor-phase epitaxy (MOVPE) reactor so that the μLED array layers are grown epitaxially.

In one or more embodiments, the first p-type layer 208a and the second p-type layer 208b, may independently comprise any Group III-V semiconductors, including binary, ternary, and quaternary alloys of gallium (Ga), aluminum (Al), indium (In), and nitrogen (N), also referred to as III-nitride materials. Thus, in some embodiments, the first p-type layer 208a, and the second p-type layer 208b independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

In some embodiments, the first p-type layer 208a and the second p-type layer 208b, independently comprise a sequence of doped p-type layers. In one or more embodiments, the first p-type layer 208a and the second p-type layer 208b independently comprise a gallium nitride (GaN) layer. The first p-type layer 208a and the second p-type layer 208b may be independently doped with any suitable p-type dopant known to the skilled artisan. In one or more embodiments, the first p-type layer 208a and the second p-type layer 208b may independently be doped with magnesium (Mg). In one or more embodiments, the first p-type layer 208a and the second p-type layer 208b independently comprise a first magnesium doped p-type aluminum gallium nitride layer, a magnesium doped p-type gallium nitride layer, and a second magnesium doped p-type aluminum gallium nitride layer.

In one or more embodiments, the key differentiators for the epitaxy used in this μLED array 200 versus known μLED arrays are the reverse polarization orientation discussed above and the use of wider than typical quantum wells in an application where a large color shift is intentionally wanted. For example, the well width that optimizes internal quantum efficiency (IQE) at high current density might be 3 nm, whereas it might be preferable to increase the width to 5 nm in one or more embodiments. In one or more embodiments, the well width may be in a range of from 2 nm to 8 nm.

FIG. 10 illustrates a cross-section schematic after processing the second variation 200 into a microLED array 250. The arrows 226, 228, having different dash patterns, indicate the recombination paths resulting in red, green, and blue emission. A color-shifting red active region similar to the one illustrated in FIG. 4 may be used that produces red emission with small bias on terminal B and green emission with large bias on terminal B. As recognized by one of skill in the art, the second variation 200 of FIG. 9 has been rotated 180 degrees to form the microLED array 250.

Referring to FIG. 10, a microLED wafer 250 is fabricated by first doing an acceptor activation anneal. A reflective p-contact electrode (p-mirror) 218 is deposited. The reflective p-contact electrode (p-mirror) 218 may comprise any suitable material known to the skilled artisan. In one or more embodiments, the reflective p-contact electrode (p-mirror) 218 comprises one or more of aluminum (Al), platinum (Pt), silver (Ag), and the like. In other embodiments, the reflective p-contact electrode (p-mirror) 218 may comprise a bilayer of a reflective material (i.e., one or more of aluminum (Al), platinum (Pt), silver (Ag), and the like) and indium-tin oxide (ITO), with the ITO being the part of the bilayer in direct contact with the second p-type layer 208b.

In one or more embodiments, the reflective p-contact electrode (p-mirror) 218 is then bonded to a backplane wafer 220, which might be pre-coated with similar metals to facilitate wafer bonding. In one or more embodiments, the backplane wafer 220 contains vias 222 and 224 between the bonding surface and circuitry within or on the opposite face of the backplane wafer 220.

Still referring to FIG. 10, in one or more embodiments, the first n-type layer 204a and the second n-type layer 204b are etched, e.g., by dry etching, to form openings for electrical contacts 214, to isolate pixels, and to access the via 224 to backplane terminal B. In one or more embodiments, there are a total of two etch levels 252 and 254, which is a more manageable number than in known RGB μLED arrays.

In one or more embodiments, a dielectric layer 212 is conformally deposited on the entire wafer 250. In one or more embodiments, the dielectric layer 212 includes, but is not limited to, oxides, e.g., silicon oxide (SiO₂), aluminum oxide (Al₂O₃), nitrides, e.g., silicon nitride (Si₃N₄). In one or more embodiments, the dielectric layer 212 comprises silicon nitride (Si₃N₄), silicon oxide (SiO₂), or a multi-layer of silicon dioxide (SiO₂) and silicon nitride (Si₃N₄). In some embodiments, the dielectric layer 212 composition is non-stoichiometric relative to the ideal molecular formula. For example, in some embodiments, the dielectric layer 212 includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 212 is removed from electrical contact points using dry etching. Ohmic contact metals 214 are deposited and formed in the dielectric openings. Each of the ohmic contact metals 214 are to the n-type layer 204a and 204b and may be the same metal. The ohmic contact metals 214 may comprise any suitable metal known to the skilled artisan. In one or more embodiments, the ohmic contact metals 214 comprise aluminum (Al).

Still referring to FIG. 10, a thick, partly conformal metal layer 216 is deposited over most of the mesa area. A gap 232 is left across the center of the mesa to allow light out and to electrically isolate 224 Terminal B from ground. The partly conformal metal layer 216 may comprise any suitable material known to the skilled artisan. In one or more embodiments, the partly conformal metal layer 116 has high reflectivity and stability. In one or more embodiments, the partly conformal metal layer 216 comprises aluminum (Al) or platinum (Pt). The partly conformal metal layer 216 connects the second n-type layer 204b with the via 224 to backplane Terminal B. The layer 216 may be comprised of a stack of multiple different metal thin films, for example a first metal such as Al or silver (Ag) with the property of high reflectivity and second metal with better chemical stability such as titanium (Ti), chromium (Cr), tungsten (W), gold (Au) or Pt. The partly conformal metal layer 216 connects the second n-type layer 204b with the via 224 to backplane Terminal B.

In other, unillustrated embodiments, a different implementation of Variation B which has a red active region operated by fixed current supplied by Terminal A, and a green/blue voltage-controlled color switching active region connected to Terminal B can be produced.

Variation A 100 of FIGS. 5 and 6 is more complicated, but capable of higher system efficiency than Variation B 200 of FIGS. 9 and 10. In one or more embodiments, A green active region designed to emit green at higher current (Variation A) can be optimized to have higher internal quantum efficiency than a red active region which switches to green emission with high bias voltage. For InGaN red active regions the quantum efficiency tends to peak at very low current density. A similar argument applies to the relative IQE of a green/blue switching active region versus an active region designed specifically to emit blue at high current density.

Visualization systems, such as virtual reality systems and augmented reality systems, are becoming increasingly more common in fields such as entertainment, education, medicine, and business.

In a virtual reality system, a display can present to a user a view of scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

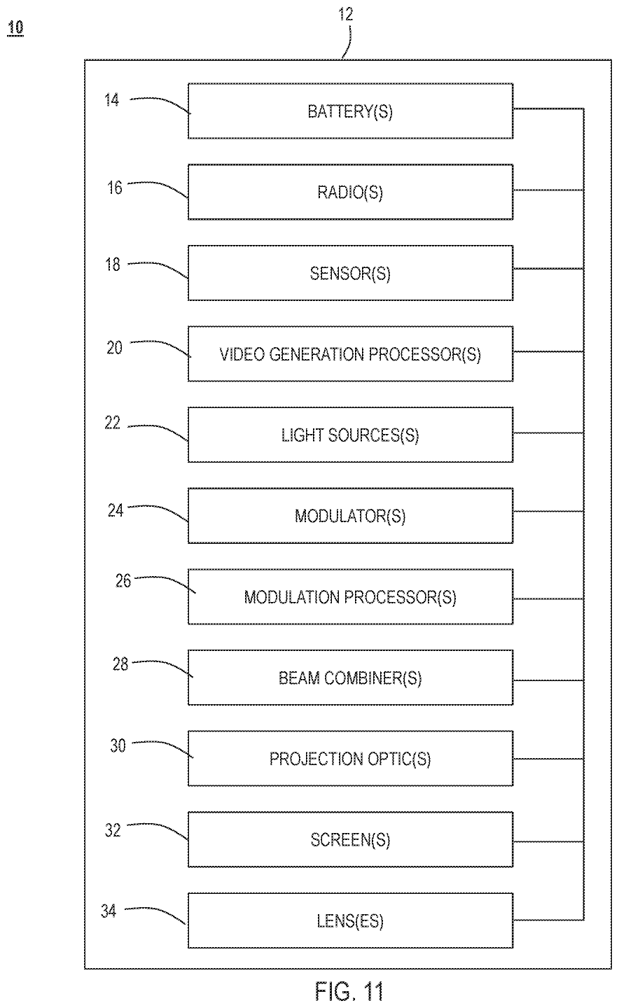

FIG. 11 shows a block diagram of an example of a visualization system 10 that utilizes the μLED array of one or more embodiments. The visualization system 10 can include a wearable housing 12, such as a headset or goggles. The housing 12 can mechanically support and house the elements detailed below. In some examples, one or more of the elements detailed below can be included in one or more additional housings that can be separate from the wearable housing 12 and couplable to the wearable housing 12 wirelessly and/or via a wired connection. For example, a separate housing can reduce the weight of wearable goggles, such as by including batteries, radios, and other elements. The housing 12 can include one or more batteries 14, which can electrically power any or all of the elements detailed below. The housing 12 can include circuitry that can electrically couple to an external power supply, such as a wall outlet, to recharge the batteries 14. The housing 12 can include one or more radios 16 to communicate wirelessly with a server or network via a suitable protocol, such as WiFi.

The visualization system 10 can include one or more sensors 18, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 18 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 18 can capture a real-time video image of the surroundings proximate a user.

The visualization system 10 can include one or more video generation processors 20. The one or more video generation processors 20 can receive from a server and/or a storage medium, scene data that represents a three-dimensional scene, such as a set of position coordinates for objects in the scene or a depth map of the scene. The one or more video generation processors 20 can receive one or more sensor signals from the one or more sensors 18. In response to the scene data, which represents the surroundings, and at least one sensor signal, which represents the location and/or orientation of the user with respect to the surroundings, the one or more video generation processors 20 can generate at least one video signal that corresponds to a view of the scene. In some examples, the one or more video generation processors 20 can generate two video signals, one for each eye of the user, that represent a view of the scene from a point of view of the left eye and the right eye of the user, respectively. In some examples, the one or more video generation processors 20 can generate more than two video signals and combine the video signals to provide one video signal for both eyes, two video signals for the two eyes, or other combinations.

The visualization system 10 can include one or more light sources 22 that can provide light for a display of the visualization system 10. Suitable light sources 22 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and has light-emitting diode elements that are individually addressable and controllable (and/or controllable in groups and/or subsets), an array of micro-light-emitting diodes (microLEDs), and others.

A light-emitting diode can be a white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, which has a wavelength greater than a wavelength of the excitation light.

The one or more light sources 22 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The visualization system 10 can include one or more modulators 24. The modulators 24 can be implemented in one of at least two configurations.

In a first configuration, the modulators 24 can include circuitry that can modulate the light sources 22 directly. For example, the light sources 22 can include an array of light-emitting diodes, and the modulators 24 can directly modulate the electrical power, electrical voltage, and/or electrical current directed to each light-emitting diode in the array to form modulated light. The modulation can be performed in an analog manner and/or a digital manner. In some examples, the light sources 22 can include an array of red light-emitting diodes, an array of green light-emitting diodes, and an array of blue light-emitting diodes, and the modulators 24 can directly modulate the red light-emitting diodes, the green light-emitting diodes, and the blue light-emitting diodes to form the modulated light to produce a specified image.

In a second configuration, the modulators 24 can include a modulation panel, such as a liquid crystal panel. The light sources 22 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 24 can include multiple modulation panels that can modulate different colors of light. For example, the modulators 24 can include a red modulation panel that can attenuate red light from a red-light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 24 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 10 can include one or more modulation processors 26, which can receive a video signal, such as from the one or more video generation processors 20, and, in response, can produce an electrical modulation signal. For configurations in which the modulators 24 directly modulate the light sources 22, the electrical modulation signal can drive the light sources 24. For configurations in which the modulators 24 include a modulation panel, the electrical modulation signal can drive the modulation panel.

The visualization system 10 can include one or more beam combiners 28 (also known as beam splitters 28), which can combine light beams of different colors to form a single multi-color beam. For configurations in which the light sources 22 can include multiple light-emitting diodes of different colors, the visualization system 10 can include one or more wavelength-sensitive (e.g., dichroic) beam splitters 28 that can combine the light of different colors to form a single multi-color beam.

The visualization system 10 can direct the modulated light toward the eyes of the viewer in one of at least two configurations. In a first configuration, the visualization system 10 can function as a projector, and can include suitable projection optics 30 that can project the modulated light onto one or more screens 32. The screens 32 can be located a suitable distance from an eye of the user. The visualization system 10 can optionally include one or more lenses 34 that can locate a virtual image of a screen 32 at a suitable distance from the eye, such as a close-focus distance, such as 500 mm, 750 mm, or another suitable distance. In some examples, the visualization system 10 can include a single screen 32, such that the modulated light can be directed toward both eyes of the user. In some examples, the visualization system 10 can include two screens 32, such that the modulated light from each screen 32 can be directed toward a respective eye of the user. In some examples, the visualization system 10 can include more than two screens 32. In a second configuration, the visualization system 10 can direct the modulated light directly into one or both eyes of a viewer. For example, the projection optics 30 can form an image on a retina of an eye of the user, or an image on each retina of the two eyes of the user.

For some configurations of augmented reality systems, the visualization system 10 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

### Embodiments

Various embodiments are listed below. It will be understood that the embodiments listed below may be combined with all aspects and other embodiments in accordance with the scope of the invention.

Embodiment (a). A light emitting diode (LED) array comprising: a first light emitting stack on a second light emitting stack, the second light emitting stack on a third light emitting stack, the third light emitting stack on a reflective p-contact electrode bonded to a backplane, wherein the first light emitting stack comprises a first electrical contact on a first n-type layer on a first color active region, the first color active region on a first p-type layer, and the first p-type layer on a first tunnel junction, the second light emitting stack comprises a second electrical contact on a second n-type layer in contact with the first tunnel junction and on a second tunnel junction, the second tunnel junction on a second p-type layer, and the second p-type layer on a second color active region, and the third light emitting stack comprises a third electrical contact on a third n-type layer in contact with the second color active region and on a third p-type layer.

Embodiment (b). The LED array of embodiment (a), further comprising a dielectric layer surrounding the first light emitting stack, the second light emitting stack, and the third light emitting stack.

Embodiment (c). The LED array of embodiment (a) to embodiment (b), further comprising a reflective metal layer on the dielectric layer.

Embodiment (d). The LED array of embodiment (a) to embodiment (c), wherein the first light emitting stack and the second light emitting stack share the second n-type layer connected to the second electrical contact.

Embodiment (e). The LED array of embodiment (a) to embodiment (d), wherein when the first light emitting stack and the second light emitting stack are driven in parallel, an aggregate color of emission is controlled by voltage.

Embodiment (f). The LED array of embodiment (a) to embodiment (e), further comprising an electrode grid.

Embodiment (g). The LED array of embodiment (a) to embodiment (f), wherein the first n-type layer, the second n-type layer, and the third n-type layer independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (h). The LED array of embodiment (a) to embodiment (g), wherein the first n-type layer, the second n-type layer, and the third n-type layer comprise gallium nitride (GaN).

Embodiment (i). The LED array of embodiment (a) to embodiment (h), wherein the first electrical contact, the second electrical contact, and the third electrical contact independently comprise aluminum.

Embodiment (j). The LED array of embodiment (a) to embodiment (i), wherein the reflective p-contact electrode comprises one or more of aluminum (Al), platinum (Pt), silver (Ag).

Embodiment (k). The LED array of embodiment (a) to embodiment (j), wherein the reflective p-contact electrode comprises a bilayer comprising indium tin oxide (ITO) and one or more of aluminum (Al), platinum (Pt), and silver (Ag).

Embodiment (l). A method of manufacturing an LED array, the method comprising: sequentially forming at least three p-n junctions on an epitaxial wafer to form an epitaxial stack, the epitaxial stack comprising at least one n-type layer and at least one p-type layer and having a color active region embedded between the at least one n-type layer and at least one p-type layer; depositing a reflective p-contact electrode on the epitaxial stack; bonding the reflective p-contact electrode to a backplane wafer; dry etching the epitaxial stack to access the at least one n-type layer to form electrical contacts and a mesa; conformally depositing a dielectric layer over the mesa; removing a portion of the dielectric layer to form a dielectric opening on a top surface of the mesa, the dielectric opening exposing the at least one n-type layer; depositing Ohmic contacts in the dielectric opening to form an electrical contact; depositing a conformal metal layer over a portion of the mesa and forming a gap across a center of the mesa to allow light out; and depositing an electrode grid over a top of the LED array.

Embodiment (m). The method of embodiment (l), further comprising annealing the epitaxial stack prior to depositing the reflective p-contact electrode.

Embodiment (n). The method of embodiment (l) to embodiment (m), wherein the epitaxial stack comprises: a first light emitting stack comprising a first n-type layer on a first color active region, the first color active region on a first p-type layer, the first p-type layer on a first tunnel junction; a second light emitting stack comprising a second n-type layer in contact with the first tunnel junction and on a second tunnel junction, the second tunnel junction on a second p-type layer, and the second p-type layer on a second color active region; and a third light emitting stack comprising a third n-type layer in contact with the second color active region and on a third p-type layer.

Embodiment (o). The method of embodiment (l) to embodiment (n), wherein when the first light emitting stack and the second light emitting stack are driven in parallel, an aggregate color of emission is controlled by voltage.

Embodiment (p). The method of embodiment (l) to embodiment (o), wherein the first n-type layer, the second n-type layer, and the third n-type layer independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (q). The method of embodiment (l) to embodiment (p), wherein the first n-type layer, the second n-type layer, and the third n-type layer comprise gallium nitride (GaN).

Embodiment (r). The method of embodiment (l) to embodiment (q), wherein the electrical contact comprises aluminum.

Embodiment (s). The method of embodiment (l) to embodiment (r), wherein the reflective p-contact electrode comprises one or more of aluminum (Al), platinum (Pt), silver (Ag), or wherein the reflective p-contact electrode comprises a bilayer comprising indium tin oxide (ITO) and one or more of aluminum (Al), platinum (Pt), and silver (Ag).

Embodiment (t). A visualization system, comprising: a battery; a radio; a sensor; a video generation process; a light source comprising the LED array of any one of embodiments (a) to (r); a modulator; a modulation processor; a beam combiner; a projection optic; a screen; and a lens.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A light emitting diode (LED) array comprising:
a first light emitting stack on a second light emitting stack, the second light emitting stack on a third light emitting stack, the third light emitting stack on a reflective p-contact electrode bonded to a backplane, wherein
the first light emitting stack comprises a first electrical contact on a first n-type layer on a first color active region, the first color active region on a first p-type layer, and the first p-type layer on a first tunnel junction,
the second light emitting stack comprises a second electrical contact on a second n-type layer in contact with the first tunnel junction and on a second tunnel junction, the second tunnel junction on a second p-type layer, and the second p-type layer on a second color active region, and
the third light emitting stack comprises a third electrical contact on a third n-type layer in contact with the second color active region and on a third p-type layer.

2. The LED array of claim 1, further comprising a dielectric layer surrounding the first light emitting stack, the second light emitting stack, and the third light emitting stack.

3. The LED array of claim 2, further comprising a reflective metal layer on the dielectric layer.

4. The LED array of claim 1, wherein the first light emitting stack and the second light emitting stack share the second n-type layer connected to the second electrical contact.

5. The LED array of claim 4, wherein when the first light emitting stack and the second light emitting stack are driven in parallel, an aggregate color of emission is controlled by voltage.

6. The LED array of claim 1, further comprising an electrode grid.

7. The LED array of claim 1, wherein the first n-type layer, the second n-type layer, and the third n-type layer independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

8. The LED array of claim 7, wherein the first n-type layer, the second n-type layer, and the third n-type layer comprise gallium nitride (GaN).

9. The LED array of claim 1, wherein the first electrical contact, the second electrical contact, and the third electrical contact independently comprise aluminum.

10. The LED array of claim 1, wherein the reflective p-contact electrode comprises one or more of aluminum (Al), platinum (Pt), silver (Ag).

11. The LED array of claim 1, wherein the reflective p-contact electrode comprises a bilayer comprising indium tin oxide (ITO) and one or more of aluminum (Al), platinum (Pt), and silver (Ag).

12. A method of manufacturing an LED array, the method comprising:
sequentially forming at least three p-n junctions on an epitaxial wafer to form an epitaxial stack, the epitaxial stack comprising at least one n-type layer and at least one p-type layer and having a color active region embedded between the at least one n-type layer and at least one p-type layer;
depositing a reflective p-contact electrode on the epitaxial stack;
bonding the reflective p-contact electrode to a backplane wafer;
dry etching the epitaxial stack to access the at least one n-type layer to form electrical contacts and a mesa;
conformally depositing a dielectric layer over the mesa;
removing a portion of the dielectric layer to form a dielectric opening on a top surface of the mesa, the dielectric opening exposing the at least one n-type layer;
depositing Ohmic contacts in the dielectric opening to form an electrical contact;
depositing a conformal metal layer over a portion of the mesa and forming a gap across a center of the mesa to allow light out; and
depositing an electrode grid over a top of the LED array.

13. The method of claim 12, further comprising annealing the epitaxial stack prior to depositing the reflective p-contact electrode.

14. The method of claim 12, wherein the epitaxial stack comprises:
a first light emitting stack comprising a first n-type layer on a first color active region, the first color active region on a first p-type layer, the first p-type layer on a first tunnel junction;
a second light emitting stack comprising a second n-type layer in contact with the first tunnel junction and on a second tunnel junction, the second tunnel junction on a second p-type layer, and the second p-type layer on a second color active region; and
a third light emitting stack comprising a third n-type layer in contact with the second color active region and on a third p-type layer.

15. The method of claim 14, wherein when the first light emitting stack and the second light emitting stack are driven in parallel, an aggregate color of emission is controlled by voltage.

16. The method of claim 14, wherein the first n-type layer, the second n-type layer, and the third n-type layer independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

17. The method of claim 16, wherein the first n-type layer, the second n-type layer, and the third n-type layer comprise gallium nitride (GaN).

18. The method of claim 12, wherein the electrical contact comprises aluminum.

19. The method of claim 12, wherein the reflective p-contact electrode comprises one or more of aluminum (Al), platinum (Pt), silver (Ag), or wherein the reflective p-contact electrode comprises a bilayer comprising indium tin oxide (ITO) and one or more of aluminum (Al), platinum (Pt), and silver (Ag).

20. A visualization system, comprising:
a battery;
a radio;
a sensor;
a video generation process;
a light source comprising the LED array of claim 1;
a modulator;
a modulation processor;
a beam combiner;
a projection optic;
a screen; and
a lens.
